(19) United States
(12) Patent Application Publication
(10) Pub. No.: US 2008/0266831 A1
(43) Pub. Date: Oct. 30, 2008

(54) Filter and plasma display device comprising the same

(76) Inventor: Cha-Won Hwang, Suwon-si (KR)

Correspondence Address: ROBERT E. BUSHNELL, 1522 K STREET NW, SUITE 300, WASHINGTON, DC, 20005-1202, US

(21) Appl. No.: 12/081,594

(22) Filed: Apr. 17, 2008

(30) Foreign Application Priority Data
Apr. 27, 2007 (KR) 10-2007-0041615
Mar. 27, 2008 (KR) 10-2008-0028492

(51) Int. Cl. H05K 9/00

(52) U.S. Cl. 361/818

(57) ABSTRACT

A filter including: a base film; a reflection preventing layer which is formed on one side of the base film; an electro magnetic interference (EMI) shielding layer which is formed on another side of the base film; an adhesive layer, which is formed between the EMI shielding layer and a front substrate of a display panel so as to directly adhere the filter to the front substrate of the display panel; and a conductive member which is formed to externally protrude and is formed inside a groove that penetrates the reflection preventing layer and the base film so as to electrically connect the EMI shielding layer and the conductive member. Accordingly, the filter includes a single base film and can ground the EMI shielding layer at the front surface of the plasma display device. The filter is included in a plasma display device.

### CLAIM OF PRIORITY

This application makes reference to, incorporates the same herein, and claims all benefits accruing under 35 U.S.C. § 119 from applications earlier filed in the Korean Intellectual Property Office on Apr. 27, 2007 and there duly assigned Serial No. 10-2007-0041615, and on Mar. 27, 2008 and there duly assigned Serial No. 10-2008-0028492, respectively.

### BACKGROUND OF THE INVENTION

1. Field of the Invention

The present invention relates to a filter and a plasma display device including the same, and more particularly, to a filter, which includes a single base film and can ground an electro magnetic interference (EMI) shielding layer in a front surface of a plasma display device, and a plasma display device including the filter.

2. Description of the Related Art

A plasma display device using a plasma display panel (PDP) is a flat display device that displays an image using a gas discharge, and is considered to be the next generation of flat display devices due to good display properties in terms of thinness, display capacity, brightness, contrast, afterimage, and viewing angle compared to a conventional cathode-ray tube (CRT). In the construction of a PDP, a filter is attached to a front surface of a plasma display panel in order to prevent reflection, shield electro magnetic interference (EMI), and block near infrared rays. The structure of a multi-layer filter including a plurality of base films is not simple however, and manufacturing costs of the multi-layer filter are high.

### SUMMARY OF THE INVENTION

According to an aspect of the present invention, there is provided a filter including: a base film; a reflection preventing layer which is formed on one side of the base film; an electro magnetic interference (EMI) shielding layer which is formed on the other side of the base film; an adhesive layer which is formed between the EMI shielding layer and a front substrate of a display panel so as to directly adhere the filter to the front substrate of the display panel; and a conductive member which is formed to protrude from the filter and which is contained in a groove that penetrates the reflection preventing layer and the base film so as to electrically connect the EMI shielding layer and the conductive member.

At this time, the conductive member may be an Ag electrode, the conductive member may be continuously formed along the boundary of the filter, and the width of the groove may be in a range of 10 to 100 μm.

The EMI shielding layer may include a silver halide layer having a pattern, and a copper layer plated on the silver halide layer. The silver halide layer may be formed by performing a photo etching method on the base film. The silver halide layer may be formed by forming a photosensitive resin layer on the base film and by performing a printing method on the photosensitive resin layer.

The combined thickness of the silver halide layer and the copper layer may be in a range of 2 to 6 μm.

According to another aspect of the present invention, there is provided a plasma display device comprising the filter described above.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a diagram illustrating a cross-sectional view of a filter using a plurality of base films;

FIG. 2 is a plan view of the filter of FIG. 1;

FIG. 3 is a perspective view of a filter including a single base film, according to an embodiment of the present invention;

FIG. 4 is a partial cross-sectional view of the filter illustrated in FIG. 3 taken along a line IV-IV in FIG. 3, according to an embodiment of the present invention;

FIGS. 5A through 5C are cross-sectional views illustrating a method of forming a conductive member of the filter of FIG. 3, according to an embodiment of the present invention;

FIG. 6 is a cross-sectional view of a filter including a single base film, according to another embodiment of the present invention;

FIG. 7 is a cross-sectional view of a filter including a single base film, according to another embodiment of the present invention;

FIGS. 8A through 8H are cross-sectional views illustrating a method of manufacturing a mesh type electro magnetic interference (EMI) shielding layer by using a conventional etching method;

FIG. 9 is a cross-sectional view illustrating a reflection preventing layer formed on an EMI shielding layer manufactured using the method illustrated in FIGS. 8A through 8H, according to an embodiment of the present invention;

FIGS. 10A through 10D are diagrams illustrating a method of manufacturing a mesh type EMI shielding layer by using an exposure and plating method, according to an embodiment of the present invention;

FIG. 11 is a cross-sectional view illustrating a reflection preventing layer formed on an EMI shielding layer manufactured using the method illustrated in FIGS. 10A through 10D, according to an embodiment of the present invention;

FIGS. 12A through 12D are diagrams illustrating a method of manufacturing a mesh type EMI shielding layer by using a printing method, according to another embodiment of the present invention;

FIG. 13 is a cross-sectional view illustrating a reflection preventing layer formed on an EMI shielding layer manufactured using the method illustrated in FIGS. 12A through 12D, according to an embodiment of the present invention;

FIG. 14 is a perspective view of a plasma display device including a filter according to an embodiment of the present invention; and

FIG. 15 is a partial cross-sectional view taken along a line XV-XV of FIG. 14, according to an embodiment of the present invention.

### DETAILED DESCRIPTION OF THE INVENTION

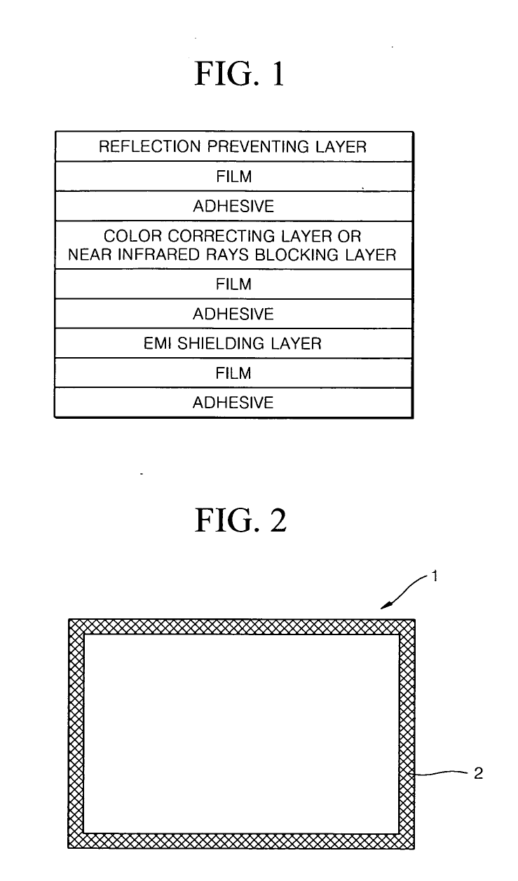

Turning now to the drawings, FIG. 1 is a cross-sectional views illustrating a plasma display device which uses a plasma display panel (PDP) in order to provide a flat display device that displays an image using a gas discharge, thus is considered to be the next generation of flat display devices due to good display properties in terms of thinness, display capacity, brightness, contrast, afterimage, and viewing angle compared to a conventional cathode-ray tube (CRT).

A filter 1 is attached to a front surface of a plasma display panel in order to prevent reflection, shield electro magnetic interference (EMI), and block near infrared rays. As shown by FIG. 1, the diagram illustrate in a cross-sectional view, a filter 1 including three base films. This filter includes a reflection preventing layer, a near infrared rays blocking layer, and an EMI shielding layer, each of which is disposed on a corresponding one of the three base films. An adhesive is used to adhere filter 1 to a front surface of a plasma display panel. FIG. 2 is a plan view of the filter 1 as illustrated in FIG. 1. Since filter 1 includes a plurality of base films, an EMI shielding layer 2 may be exposed to a front surface (the top in FIG. 2) and/or a rear surface of a plasma display panel. Accordingly, the EMI shielding layer 2 can be grounded from the front surface and/or the rear surface of the plasma display panel.

The structure of a multi-layer filter including a plurality of base films described above is not simple, and the manufacturing costs incurred by the fabrication of the multi-layer filter are high.

Hereinafter, the present invention will be described more fully with reference to the accompanying drawings, in which exemplary embodiments of the invention are shown.

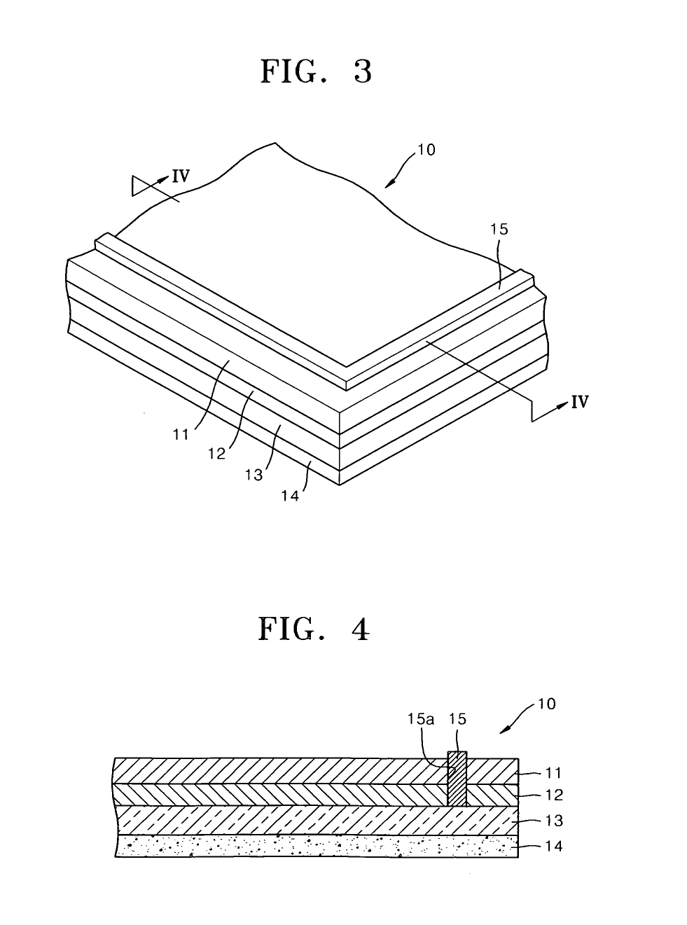

FIG. 3 is a perspective view of a filter 10 including a single base film 12, according to an embodiment of the present invention. FIG. 4 is a partial cross-sectional view of the filter 10 taken along a line IV-IV in FIG. 3, according to an embodiment of the present invention.

Referring to FIG. 3, the filter 10 according to the current embodiment includes a reflection preventing layer 11, the base film 12, an electro magnetic interference (EMI) shielding layer 13, and an adhesive layer 14, which are sequentially laminated from the top. The reflection preventing layer 11 can include 1˜3 thin laminated layers. For example, the reflection preventing layer 11 can be formed of a combination of a reflection reducing layer and a surface hardness reinforcing layer. The reflection reducing layer may be an anti-reflection (AR) layer, an anti-glare (AG) layer, or an AR/AG combination layer. Accordingly, the reflection reducing layer scatters external incident light from the surface of the reflection reducing layer, and prevents lights surrounding the filter 10 from being reflected on the surface of the reflection reducing layer.

Also, the reflection preventing layer 11 may be the surface hardness reinforcing layer. The surface hardness reinforcing layer is a hard coating layer including a hard coating material. The filter 10 can be prevented from being scratched by an external material. The hard coating material may use a polymer as a binder. The polymer may be an acryl based polymer, a urethane based polymer, an epoxy based polymer, a siloxane based polymer, or an ultraviolet (UV) curing resin, such as an oligomer. Here, a silica-based filler may be further added in order to increase hardness of the reflection preventing layer 11.

The reflection preventing layer 11 may have thickness in a range of 5.0˜10.0 μm, hardness of 3 H, and haze of 1˜10%, but is not limited thereto.

The base film 12 may be formed of a material through which visible light can 11 transmit, and enables the filter 10 to directly adhere to a front surface of a plasma display device. The base film 12 may be any transparent material that can easily adhere to a material such as glass or plastic in terms of an interface characteristic. Also, the base film 12 may be formed of a flexible material for transport convenience and adhering process convenience.

The base film 12 will now be described in detail. The base film 12 may be formed of polyethersulphone (PES), polyacrylate (PAR), polyetherimide (PEI), polyethyelenen napthalate (PEN), polyethyeleneterepthalate (PET), polyphenylene sulfide (PPS), polyallylate, polyimide, polycarbonate (PC), cellulose triacetate (TAC), or cellulose acetate propinonate (CAP), and preferably formed of PC, PET, TAC, or PEN.

The base film 12 may be colored to have a predetermined color. By controlling a coloring condition of the base film 12, transmissivity of visible light through the filter 10 can be controlled. For example, when the base film 12 is dark colored, the transmissivity of visible light decreases. Also, the color of the transmitted visible light can be controlled. In other words, the color of the base film 12 may be determined by a user or in order to improve chromatic purity of the plasma display device employing the filter 10. Also, the base film 12 may be colored in a pattern of colors corresponding to the sub-pixels of a plasma display panel of the plasma display device. However, the base film 12 may be variously colored for color correction of the base film 12.

The EMI shielding layer 13 shields EMI that is generated from the plasma display panel and which is harmful to the human body. The EMI shielding layer 13 may be formed of a conductive metal, such as copper, in a mesh form. A method of forming the EMI shielding layer 13 in a mesh form on the base film 12 will be described in detail later.

Alternatively, the EMI shielding layer 13 may be formed of a conductive layer (not shown). The conductive layer may be formed of one or more metal layers. Also, the conductive layer may be formed by stacking at least one metal layer or metal oxide layer. When a metal oxide layer and a metal layer are laminated together, the metal oxide layer can prevent oxidation or deterioration of the metal layer. Also, when the EMI shielding layer 13 is formed to have a multi-layer laminated structure, not only a surface resistance of the EMI shielding layer 13 can be corrected but transmissivity of visible light can also be controlled.

The metal layer may be formed of palladium, copper, platinum, rhodium, aluminum, iron, cobalt, nickel, zinc, ruthenium, tin, tungsten, iridium, lead (Pb), silver (Ag), or a combination thereof. Also, the metal oxide layer may be formed of tin oxide, indium oxide, antimony oxide, zinc oxide, zirconium oxide, titanium oxide, magnesium oxide, silicon oxide, aluminum oxide, metal alkoxide, indium-tin-oxide, or antimony-tin-oxide (ATO).

The conductive layer can not only shield EMI but also block near infrared rays. Accordingly, peripheral electronic devices can be prevented from malfunctioning due to near infrared rays.

The adhesive layer 14 is formed on the bottom surface of the EMI shielding layer 13 so that the filter 10 can adhere to the front surface of the plasma display panel. A difference in refractive indices of the adhesive layer 14 and the plasma display panel may not exceed a predetermined value, such as 1.0% so as to reduce the occurrence of ghost images.

The adhesive layer 14 may include a thermoplastic UV curing resin, such as an acrylate-based resin or pressure sensitive adhesive (PSA). Such adhesive layer 14 may be formed using a deep coating method, an air knife method, a roller coating method, a wire bar coating method, or a Gravure coating method.

The adhesive layer 14 may further include a compound that absorbs near infrared rays. The adhesive layer 14 may further include a coloring matter, such as a dye or a pigment, for color correction by blocking a neon light. The coloring matter selectively absorbs light in a wavelength range of 400˜700 nm, which is in the visible light domain. Specifically while discharging the plasma display panel, unnecessary visible light having a wavelength of approximately 585 nm is generated due to neon, which is a discharge gas. Accordingly, the coloring matter may be formed of a compound, such as a cyanine based compound, squarylium based compound, azomethine based compound, xanthene based compound, oxonol based compound, or azo based compound, in order to absorb the visible light. Such coloring matter may be dispersed as corpuscles in the adhesive layer 14.

Meanwhile, the filter 10 may selectively include at least one of a near infrared rays blocking layer (not shown) and a color correcting layer (not shown). As described above, near infrared rays can be blocked by the EMI shielding layer 13 or the adhesive layer 14, but if required, a separate layer may be added to strengthen the blocking of near infrared rays. The color correcting layer is used when chromatic purity of visible light incident from the plasma display device is low or when color temperature needs to be corrected.

The filter 10 according to the current embodiment of the present invention has transmissivity in a range of 20˜90% and haze in a range of 1˜11%.

In order for the EMI shielding layer 13 to shield EMI, the EMI shielding layer 13 needs to be grounded. However, in a conventional filter that includes a single base film, an EMI shielding layer is not exposed to a front surface of a plasma display device, and thus the EMI shielding layer can not be grounded. Accordingly, the filter 10 according to the current embodiment of the present invention also includes a conductive member 15.

The conductive member 15 will now be described with reference to FIGS. 3 and 4. As illustrated in FIG. 3, the conductive member 15 is formed along the boundaries of the filter 10. As illustrated in FIG. 4, the conductive member 15 is formed in a groove 15a formed in the reflection preventing layer 11 and the base film 12. Also, the conductive member 15 is exposed to the outside so as to be electrically connected to the EMI shielding layer 13. Also, the conductive member 15 may be continuously formed along the boundaries of the filter 10. Here, the conductive member 15 may be a metal electrode formed of Ag, Cu, Al, or Ni. The width of the groove 15a may be in a range of 10˜100 μm.

By forming the conductive member 15, which is exposed to the top surface of the reflection preventing layer 11, to be electrically connected to the EMI shielding layer 13, the EMI shielding layer 13 can be grounded on the front surface of the filter 10. Also, as the conductive member 15 continuously contacts the EMI shielding layer 13 along the boundaries of the filter 10, the grounding area increases, and thus grounding performance is increased. Accordingly, an EMI shielding performance is improved. Also, since the base film 12 is formed of one sheet, the structure of the filter 10 is simple, and manufacturing costs can be reduced.

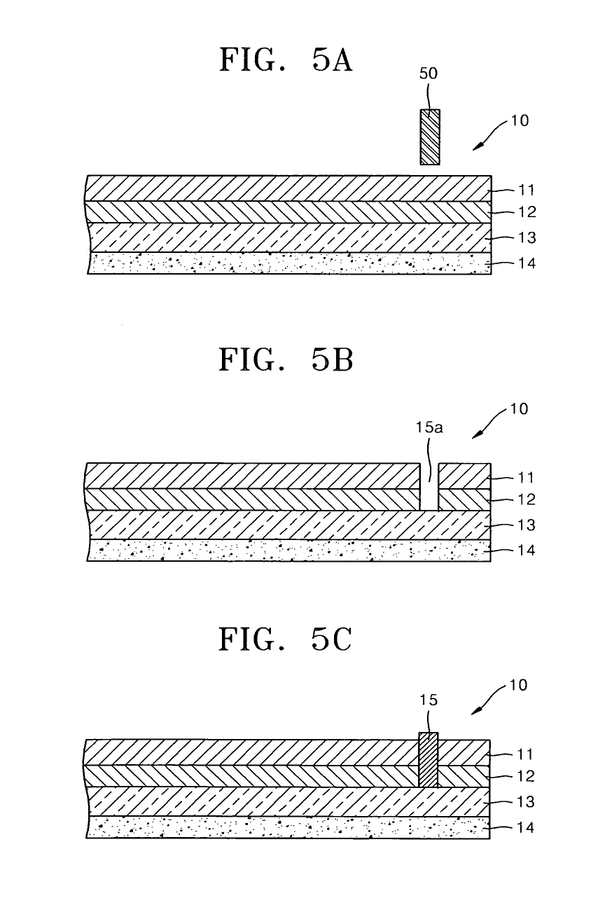

FIGS. 5A through 5C are cross-sectional views illustrating a method of forming the conductive member 15 of the filter 10, according to an embodiment of the present invention. The method of forming the conductive member 15 will be described with reference to FIGS. 5A through 5C.

First, as illustrated in FIG. 5A, the reflection preventing layer 11 is formed on the top surface of the base film 12, and the EMI shielding layer 13 is formed on the bottom surface of the base film 12. The adhesive layer 14 is formed by coating an adhesive on the bottom surface of the EMI shielding layer 13. Then, by using a cutting member 50 illustrated in FIG. 5A, the groove 15a is formed in the reflection preventing layer 11 and the base film 12 along the boundaries of the filter 10 as illustrated in FIG. 5B. The groove 15a is a space for embedding the conductive member 15. The conductive member 15 may be formed of Ag. The EMI shielding layer 13 is electrically connected to the outside by the conductive member 15, and thus the groove 15a may be formed in a part of the EMI shielding layer 13. The groove 15a may be continuously or discontinuously formed along the boundaries of the filter 10. Then, the conductive member 15 is formed by coating the Ag in the groove 15a as illustrated in FIG. 5C.

The method of forming the conductive member 15 is not limited thereto, and may be modified or changed by one of ordinary skill in the art.

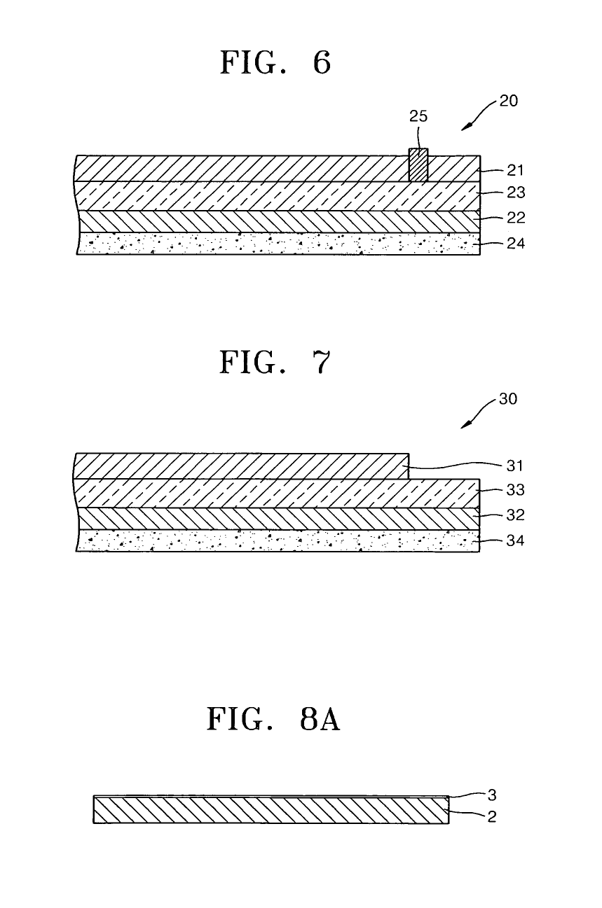

FIG. 6 is a cross-sectional view of a filter 20 including a single base film 22, according to another embodiment of the present invention. The filter 20 is formed by sequentially laminating a reflection preventing layer 21, an EMI shielding layer 23, the base film 22, and an adhesive layer 24 from the top. The difference between the filter 10 and the filter 20 is that the EMI shielding layer 23 is formed between the reflection preventing layer 21 and the base film 22, and a groove is formed in the reflection preventing layer 21 so that the EMI shielding layer 23 can be externally exposed. A conductive member 25 is formed inside the groove and protrudes from the top surface of the reflection preventing layer 21 so as to electrically connect the EMI shielding layer 23 to the outside.

FIG. 7 is a cross-sectional view of a filter 30 including a single base film 32, according to another embodiment of the present invention. The filter 30 is formed by sequentially laminating a reflection preventing layer 31, an EMI shielding layer 33, the base film 32, and an adhesive layer 34 from the top. The EMI shielding layer 33 includes an EMI shielding portion and a grounding portion. The grounding portion is formed around the EMI shielding portion. The grounding portion is configured to be electrically connected to ground potential. A difference between the filter 20 and the filter 30 is that the width of the reflection preventing layer 31 is less than the width of the base film 32, thus exposing the upper surface of the grounding portion of the EMI shielding layer 33. But the whole upper surface of the grounding portion is not needed to be exposed. Accordingly, unlike the filters 10 and 20 of FIGS. 4 and 6, the filter 30 of FIG. 7 does not require the conductive member 15 or 25.

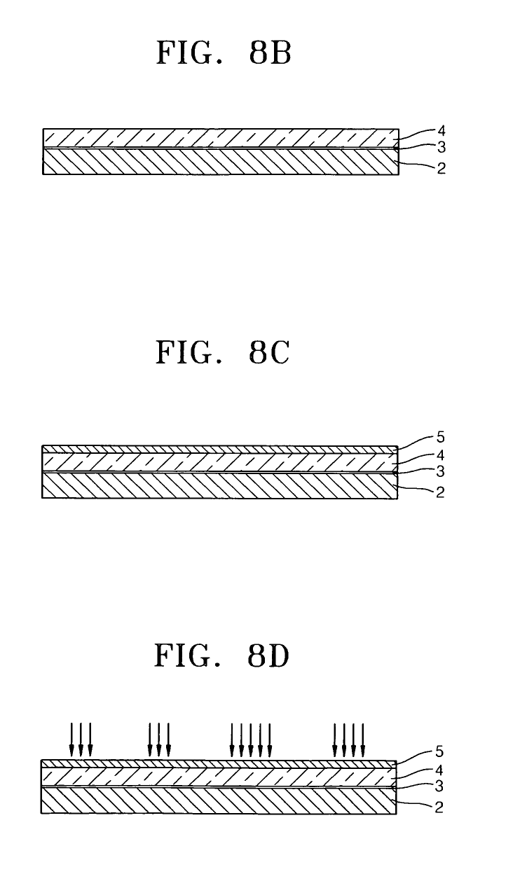

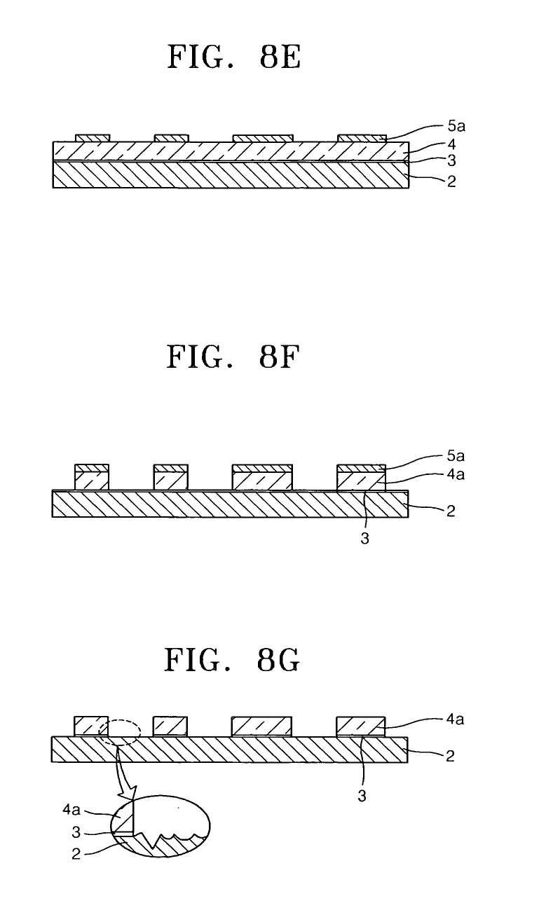

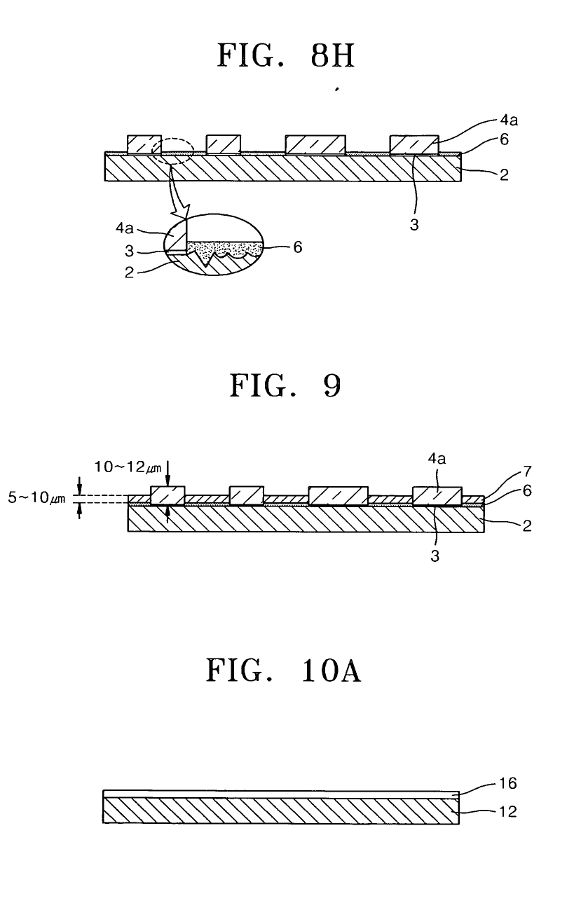

FIGS. 8A through 8H are cross-sectional views illustrating a method of manufacturing a mesh type EMI shielding layer by using a conventional etching method. Firstly, referring to FIG. 8A, an adhesive 3 is coated on one side of a base film 2, and then, referring to FIG. 8B, a thin copper film 4 is laminated on the adhesive 3. Referring to FIG. 8C, a photo resist layer 5 is formed on the thin copper film 4, and then, referring to FIG. 8D, ultraviolet rays are irradiated on the photo resist layer 5 through a pattern mask designed according to a circuit pattern. Then, referring to FIG. 8E, the photo resist layer 5a is developed. The photo resist layer 5a can be formed using a positive method, by which regions of the photo resist layer 5a which are exposed to light are developed, or a negative method, by which regions of the photo resist layer 5 which are not exposed to light are developed.

Referring to FIG. 8F, portions of the thin copper film 4 not covered by the photo resist layer 5a are etched using an etchant, and then, referring to FIG. 8G, a mesh pattern 4a formed of copper is formed by removing the photo resist layer 5a. The thickness of the thin copper film 4 is generally in a range of 10˜12 μm, and thus when the thin copper film 4 is etched, the surface of the base film 2 becomes minutely uneven. External light is scattered and thus blurred by such unevenness of the base film 2. Accordingly, a solution 6 that can prevent such diffusion should be coated on the surface of the base film 2 as shown in FIG. 8H. However, the mesh pattern 4a formed by etching the thin copper film 4 has a rectangular form, and the solution 6 is not easily coated on a corner region formed by the mesh pattern 4a and the base film 2. Thus, the manufacture of a mesh type EMI shielding layer by using a conventional etching method is completed.

FIG. 9 is a cross-sectional view of a reflection preventing layer 7 formed on an EMI shielding layer manufactured using the method illustrated in FIGS. 8A through 8H, according to an embodiment of the present invention. Referring to FIG. 9, the thickness of the reflection preventing layer 7 that is formed on the EMI shielding layer is generally in a range of 5˜10 μm, and thus the mesh pattern 4a cannot be covered by only forming a single reflection preventing layer 7. Accordingly, two reflection preventing layers 7 should be formed or the mesh pattern 4a should be reduced in thickness. When the EMI shielding layer is manufactured using such a method, only one EMI shielding layer having an exclusive size can be manufactured due to the size characteristic of a thin copper film. Thus, as the size of a filter changes, for example, as the size of the filter increases, manufacturing costs incurred to obtain a satisfactory yield also increase.

Accordingly, the mesh type EMI shielding layer may be formed using an exposure and plating method or a printing method as described below.

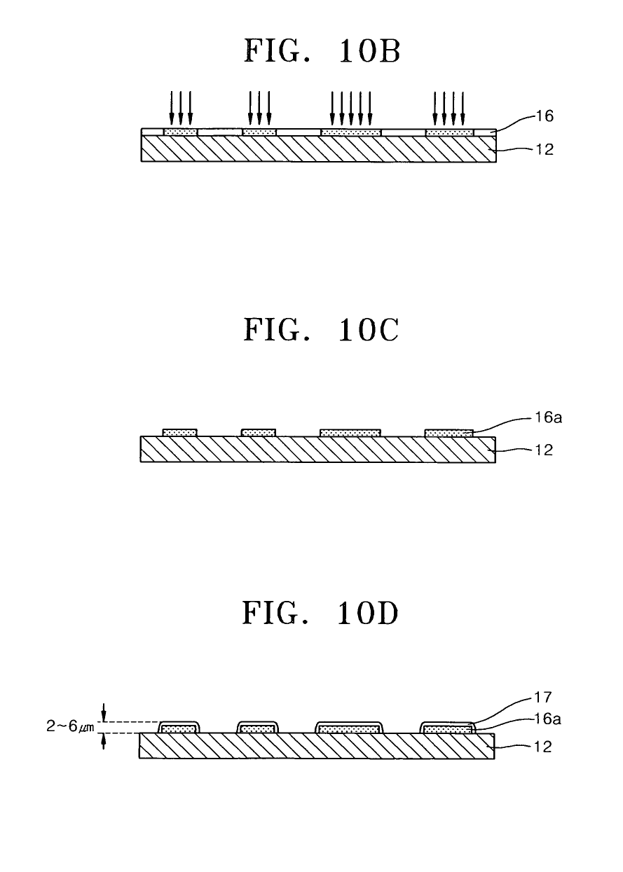

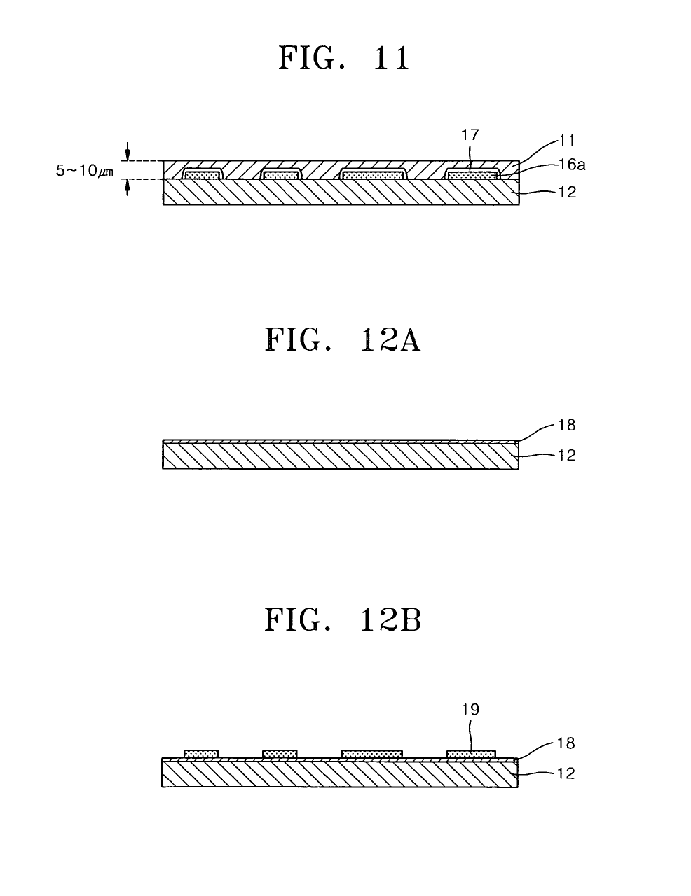

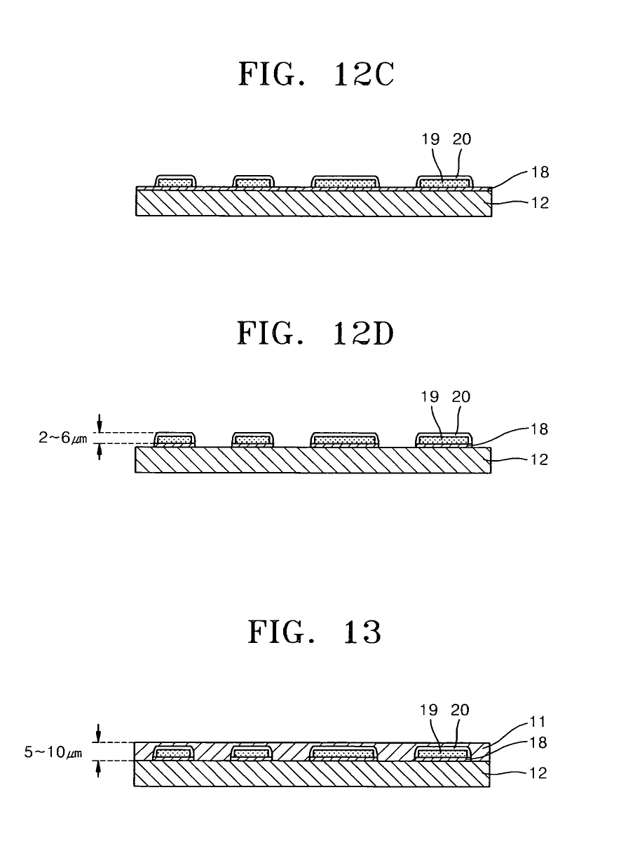

FIGS. 10A through 10D are cross-sectional views illustrating a method of manufacturing a mesh type EMI shielding layer by using an exposure and plating method, according to an embodiment of the present invention. Firstly, referring to FIG. 10A, a photosensitive silver halide 16, such as AgCl or AgNO3, is coated on a base film 12. Then, referring to FIG. 10B, ultraviolet rays are irradiated on the photosensitive silver halide 16 through a pattern mask designed according to a circuit pattern, thereby developing a photosensitive silver halide layer 16a as illustrated in FIG. 10C. The photosensitive silver halide layer 16a can be formed using a positive method, by which a photosensitive material in an exposed region is developed, or a negative method, by which a photosensitive material in a non-exposed region is developed. In the present invention any method can be used to form the photosensitive silver halide layer 16a. Since the photosensitive silver halide layer 16a is formed in a mesh pattern and is unstable, it can be easily oxidized. Accordingly, referring to FIG. 10D, copper is plated on the photosensitive silver halide layer 16a in order to form a plating layer 17, which has high electrical conductance, only on the photosensitive silver halide layer 16a. The combined thickness of the silver halide layer 16a and the plating layer 17 may be in a range of 2˜6 μm. Thus, the manufacture of a mesh type EMI shielding layer by using an exposure and plating method is completed. FIG. 11 is a cross-sectional view of a reflection preventing layer formed on the EMI shielding layer manufactured using the method illustrated in FIGS. 10A through 10D, according to an embodiment of the present invention. Referring to FIG. 11, in order to manufacture a filter such as the filter 20 or 30 illustrated in FIG. 6 or 7, a reflection preventing layer 11 is formed on the EMI shielding layer manufactured using the method illustrated in FIGS. 10A through 10D. The thickness of the reflection preventing layer 11 is generally in a range of 5˜10 μm, and thus the EMI shielding layer can be covered by forming only a single reflection preventing layer 11. Referring to FIG. 11, a combination of copper layer, i.e. the plating layer 17, coated on the silver halide layer 16a is used instead of a thin copper film as a conductive layer, and thus the conductive layer (the silver halide layer 16a and the plating layer 17) can be thin. Accordingly, only a single reflection preventing layer 11 is required, and thus the number of operations for manufacturing the filter can be reduced. Also, the surface of the base film 12 can be even since the etching process of the thin copper film is not performed and the thin photosensitive silver halide 16 is developed, and thus the solution 6, used in the manufacturing method illustrated in FIGS. 8A through 8H, may not be required to be coated, which simplifies the manufacturing process of the filter. Moreover, even when the size of the filter changes, for example, even when the size of the filter increases, the manufacturing costs incurred to obtain a satisfactory yield do not increase.

The EMI shielding layer manufactured using the method illustrated in FIGS. 10A through 10D can be used to manufacture the filters 20 and 30 in FIGS. 6 and 7. Taking into consideration that the filters 20 and 30 in FIGS. 6 and 7 are illustrated with much simplicity for better understanding and convenience, a person having an ordinary skill in the art will understand that the filter illustrated in FIG. 11 shows the filter in FIG. 6 with elimination of the conductive member 25 and the adhesive layer 24. Similarly, a person having an ordinary skill in the art will understand that the filter illustrated in FIG. 11 also shows the filter in FIG. 7 with elimination of the adhesive layer 34.

In the filter illustrated in FIG. 11, the surface of the base film 12 can be even since the thin photosensitive silver halide 16 is developed, and thus a solution that can prevent diffusion of light by unevenness of the base film 12 may not be required to be coated, which simplifies the manufacturing process of the filter. Moreover, even when the size of the filter changes, for example, even when the size of the filter increases, the expenses consumed to adjust a suitable yield do not increase.

The EMI shielding layer manufactured using the method illustrated in FIGS. 10A through 10D can be used to manufacture the filter 10 in FIG. 4. Taking into consideration that the filter 10 in FIG. 4 is illustrated with much simplicity for better understanding and convenience, a person having an ordinary skill in the art will understand that the filter in FIG. 4 can be manufactured based on the EMI shielding layer illustrated in FIG. 10D if the reflection preventing layer 11 is formed on the other side, on which the EMI shielding layer is formed, on the base film 12, the adhesive layer 14 is formed on the EMI shielding layer and the conductive member 15 is formed in the groove. In the filter illustrated in FIG. 4 comprising the EMI shielding layer illustrated in FIG. 10D, the surface of the base film 12 can be even since the thin photosensitive silver halide 16 is developed, and thus a solution that can prevent diffusion of light by unevenness of the base film 12 may not be required to be coated, which simplifies the manufacturing process of the filter. Moreover, even when the size of the filter changes, for example, even when the size of the filter increases, the expenses consumed to adjust a suitable yield do not increase.

FIGS. 12A through 12D are cross-sectional views illustrating a method of manufacturing a mesh type EMI shielding layer by using a printing method, according to an embodiment of the present invention. Firstly, referring to FIG. 12A, a photosensitive resin layer 18 is formed on a base film 12. Then, referring to FIG. 12B, a silver halide layer 19, formed of AgCl or AgNO3, is printed on the photosensitive resin layer 18 according to a circuit pattern. If the silver halide layer 19 is directly printed on the base film 12, the silver halide layer 19 can easily be detached, and so the photosensitive resin layer 18 is first formed on the base film 12.

Since the silver halide layer 19 is formed in a mesh pattern and is unstable, it can be easily oxidized, and thus copper is plated on the silver halide layer 19. Accordingly, referring to FIG. 12C, a plating layer 20, which has high electrical conductance, is formed only on the silver halide layer 19. Then, a developing process is performed in order to remove un-required resins. Accordingly, referring to FIG. 12D, portions of the photosensitive resin layer 18 not covered by the silver halide layer 19 and the plating layer 20 are removed. The combined thickness of the silver halide layer 19 and the plating layer 20 may be in a range of 2˜6 μm.

The EMI shielding layer manufactured using the method illustrated in FIGS. 12A through 12D can be used to manufacture the filters 20 and 30 in FIGS. 6 and 7. Taking into consideration that the filters 20 and 30 in FIGS. 6 and 7 are illustrated with much simplicity for better understanding and convenience, a person having an ordinary skill in the art will understand that the filter illustrated in FIG. 13 shows the filter in FIG. 6 with elimination of the conductive member 25 and the adhesive layer 24. Similarly, a person having an ordinary skill in the art will understand that the filter illustrated in FIG. 13 also shows the filter in FIG. 7 with elimination of the adhesive layer 34.

In the filter illustrated in FIG. 13, the EMI shielding layer is 2˜6 μm thick and the reflection preventing layer 11, which is 5˜10 μm thick, is coated on the EMI shielding layer and the base film 12. Accordingly, unlike the conventional method illustrated in FIG. 9, the reflection preventing layer 11 can fully cover the EMI shielding layer by coating just one time to the extent that the EMI shielding layer is buried in the reflection preventing layer 11. Thus, only a single reflection preventing layer 11 is required, and thus the number of operations for manufacturing the film 20 or 30 can be reduced. Also, the surface of the base film 12 can be even since the thin silver halide 19 is developed, and thus a solution that can prevent diffusion of light by unevenness of the base film 12 may not be coated, which simplifies the manufacturing process of the filter. Moreover, even when the size of the filter changes, for example, even when the size of the filter increases, the expenses consumed to adjust a suitable yield do not increase.

The EMI shielding layer manufactured using the method illustrated in FIGS. 12A through 12D can be used to manufacture the filter 10 in FIG. 4. Taking into consideration that the filter 10 in FIG. 4 is illustrated with much simplicity for better understanding and convenience, a person having an ordinary skill in the art will understand that the filter in FIG. 4 can be manufactured based on the EMI shielding layer illustrated in FIG. 12D if the reflection preventing layer 11 is formed on the other side, on which the EMI shielding layer is formed, on the base film 12, the adhesive layer 14 is formed on the EMI shielding layer and the conductive member 15 is formed in the groove. In the filter illustrated in FIG. 4 comprising the EMI shielding layer illustrated in FIG. 12D, the surface of the base film 12 can be even since the thin silver halide 19 is developed, and thus a solution that can prevent diffusion of light by unevenness of the base film 12 may not be coated, which simplifies the manufacturing process of the filter 10. Moreover, even when the size of the filter 10 changes, for example, even when the size of the filter 10 increases, the expenses consumed to adjust a suitable yield do not increase.

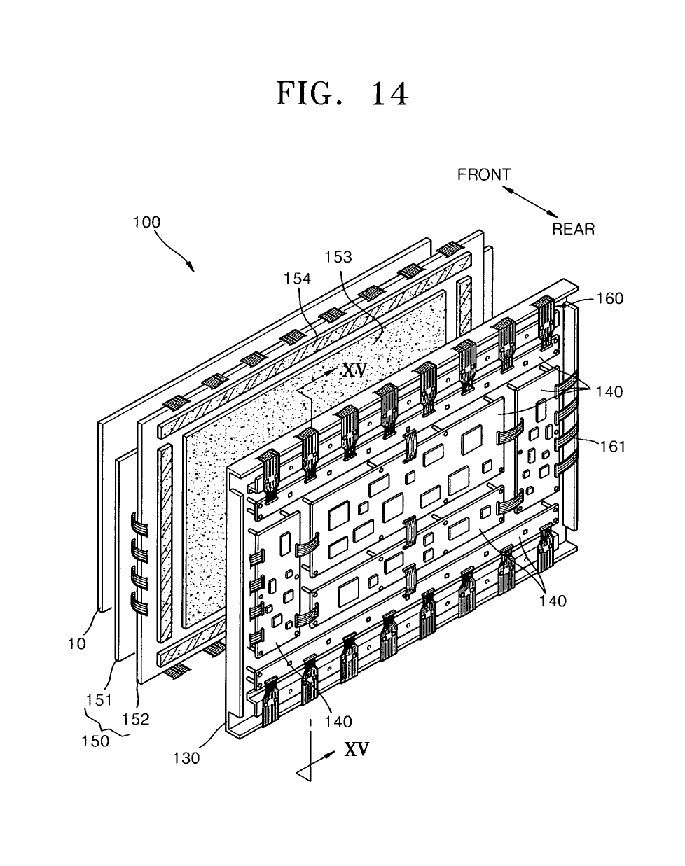

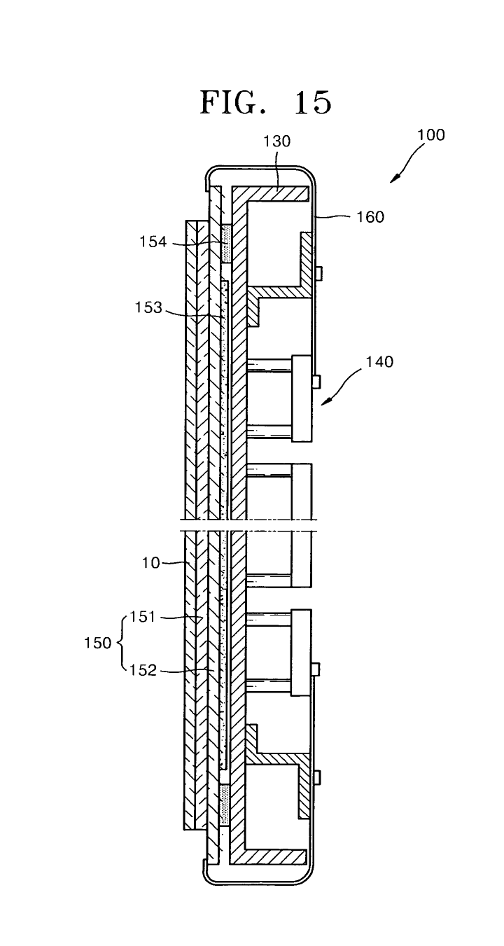

FIG. 14 is a perspective view of a plasma display device 100 including a filter 10, according to an embodiment of the present invention, and FIG. 15 is a partial cross-sectional view taken along a line XV-XV of FIG. 14, according to an embodiment of the present invention.

Referring to FIGS. 14 and 15, the plasma display device 100 according to the current embodiment of the present invention includes a plasma display panel 150, a chassis 130, and a circuit unit 140. The filter 10, which is a filter according to the present invention, is attached to the front surface of the plasma display panel 150. An adhesive such as a double-sided adhesive tape 154 may be used to combine the plasma display panel 150 and the chassis 130, and a thermal conductive member 153 may be disposed between the chassis 130 and the plasma display panel 150 so as to emit heat generated while operating the plasma display panel 150 through the chassis 130.

The plasma display panel 150 produces an image through gas discharge, and includes a front panel 151 and a rear panel 152 which are combined together. The filter 10, 20, or 30 according to the previous embodiment of the present invention can be adhered to the front surface of the plasma display panel 150 by using an adhesive layer 14. Although the filter is denoted by 10 in FIG. 14, it is obvious that the filter 20 or 30 can also be adhered to the front surface of the plasma display panel 150.

EMI of the plasma display panel 150 is shielded by the filter 10, and a glare phenomenon is reduced. Also, infrared rays and neon light can be blocked. Moreover, since the filter 10 is directly adhered to the front surface of the plasma display panel 150, problems caused by ghost images can be fundamentally resolved.

Also, unlike a conventional directly adhered base film filter that includes between two and four base films, the filter 10 has a simple structure and low manufacturing expenses.

The chassis 130 is disposed on the rear of the plasma display panel 150, and structurally supports the plasma display panel 150. The chassis 130 may be formed of a metal having excellent hardness, such as aluminum or iron, or formed of plastic.

The thermal conductive member 153 is disposed between the plasma display panel 150 and the chassis 130. Also, the double sided adhesive tape 154 is disposed along the boundaries of the thermal conductive member 153. The double sided adhesive tape 154 performs a function of fixing the plasma display panel 150 and the chassis 130 to each other.

The circuit unit 140 is disposed on the rear of the chassis 130. The circuit unit 140 is wired with circuits that drive the plasma display panel 150. The circuit unit 140 transmits electric signals to the plasma display panel 150 through signal transmitting means. The signal transmitting means may be one of a flexible printed cable (FPC), a tape carrier package (TCP), and a chip on film (COF). In the current embodiment, FPCs 161 are disposed on the right and left of the chassis 130 and TCPs 160 are disposed on the top and bottom of the chassis 130.

As described above, the filter of the present invention is applied to a plasma display panel, but is not limited thereto, and can be adhered to the front surface of various display devices.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A filter comprising:
a base film;
a reflection preventing layer which is formed on one side of the base film;
an electro magnetic interference (EMI) shielding layer which is formed on the other side of the base film;
an adhesive layer which is formed between the EMI shielding layer and a front substrate of a display panel so as to directly adhere the filter to the front substrate of the display panel; and
a conductive member which is formed to protrude from the filter and which is contained in a groove that penetrates the reflection preventing layer and the base film so as to electrically connect the EMI shielding layer and the conductive member.

2. A filter comprising:
a base film;
an EMI shielding layer which is formed on one side of the base film;
a reflection protective layer which is formed on the EMI shielding layer;
an adhesive layer which is formed on the other side of the base film so as to directly adhere the filter to a front substrate of a display panel; and
a conductive member which is formed to protrude from the filter and which is contained in a groove that is formed to penetrate the reflection preventing layer so as to electrically connect the conductive member and the EMI shielding layer.

3. A filter comprising:
a base film;
an EMI shielding layer which is formed on one side of the base film, and comprises an EMI shielding portion and a grounding portion that is formed around the EMI shielding portion;
a reflection preventing layer which is formed on the EMI shielding layer; and
an adhesive layer which is formed on the other side of the base film so as to directly adhere the filter to a front substrate of a display panel,
wherein at least a part of the grounding portion of the EMI shielding layer is exposed towards the reflection preventing layer.

4. The filter recited in claim 1, wherein the EMI shielding layer comprises a silver halide layer having a pattern, and a copper layer plated on the silver halide layer.

5. The filter recited in claim 4, wherein the silver halide layer is formed by performing a photo etching method on the base film.

6. The filter recited in claim 4, wherein the silver halide layer is formed by forming a photosensitive resin layer on the base film and by performing a printing method on the photosensitive resin layer.

7. The filter recited in claim 4, wherein the combined thickness of the silver halide layer and the copper layer is in a range of 2 to 6 μm.

8. The filter recited in claim 1, wherein the conductive member is formed of any one selected from a group consisting of Ag, Cu, Al, and Au.

9. The filter recited in claim 1, wherein the conductive member is continuously formed along the boundary of the filter.

10. The filter recited in claim 1, wherein the width of the groove is in a range of 10 to 100 μm.

11. The filter recited in claim 1, wherein the adhesive layer comprises a pigment or a dye.

12. The filter recited in claim 1, wherein said filter is embodied in a plasma display device.

13. The filter recited in claim 2, wherein the conductive member is formed of any one selected from a group consisting of Ag, Cu, Al, and Au.

14. The filter recited in claim 2, wherein the conductive member is continuously formed along the boundary of the filter.

15. The filter recited in claim 2, wherein the width of the groove is in a range of 10 to 100 μm.

16. The filter recited in claim 2, wherein the EMI shielding layer comprises a silver halide layer having a pattern, and a copper layer plated on the silver halide layer.

17. The filter recited in claim 16, wherein the silver halide layer is formed by performing a photo etching method on the base film.

18. The filter recited in claim 16, wherein the silver halide layer is formed by forming a photosensitive resin layer on the base film and by performing a printing method on the photosensitive resin layer.

19. The filter recited in claim 16, wherein the combined thickness of the silver halide layer and the copper layer is in a range of 2 to 6 μm.

20. The filter recited in claim 2, wherein the adhesive layer comprises a pigment or a dye.

21. The filter recited in claim 2, wherein said filter is embodied in a plasma display device.

22. The filter recited in claim 3, wherein the EMI shielding layer comprises a silver halide layer having a pattern, and a copper layer plated on the silver halide layer.

23. The filter recited in claim 22, wherein the silver halide layer is formed by performing a photo etching method on the base film.

24. The filter recited in claim 22, wherein the silver halide layer is formed by forming a photosensitive resin layer on the base film and by performing a printing method on the photosensitive resin layer.

25. The filter recited in claim 22, wherein the combined thickness of the silver halide layer and the copper layer is in a range of 2 to 6 μm.

26. The filter recited in claim 3, wherein the adhesive layer comprises a pigment or a dye.

27. The filter recited in claim 3, wherein said filter is embodied in a plasma display device.
